(19) United States
(12) Patent Application Publication
(10) Pub. No.: US 2023/0108754 A1
(43) Pub. Date: Apr. 6, 2023

(54) System and Method for Hyperloop State Estimation of Multiple Axes

(71) Applicant: Hyperloop Technologies, Inc., Los Angeles, CA (US)

(72) Inventors: Ke Sun, Los Angeles, CA (US); Alexander Joseph Yuen, Los Angeles, CA (US)

(73) Assignee: Hyperloop Technologies, Inc., Los Angeles, CA (US)

(21) Appl. No.: 17/952,816

(22) Filed: Sep. 26, 2022

Related U.S. Application Data
(60) Provisional application No. 63/278,461, filed on Nov. 11, 2021.
(60) Provisional application No. 63/271,530, filed on Oct. 25, 2021.
(60) Provisional application No. 63/253,123, filed on Oct. 6, 2021.

(51) Int. Cl. B61B 13/08; B61B 13/10

(52) U.S. Cl. CPC B61B 13/08; B61B 13/10

(57) ABSTRACT

A solution is disclosed for a state estimation system and method configured for a hyperloop vehicle. Further, the state estimation system provides an estimate of the future position and/or orientation of the hyperloop vehicle such that the hyperloop vehicle can maintain safe, efficient flight during a journey. The state estimation system utilizes a number of sensors to gather data in order to perform state estimation using a Kalman filter. The state estimation is then sent to a motion execution controller such that the state estimation may be translated into commands for engines disposed throughout the hyperloop vehicle such that the position and/or orientation may be reached by hyperloop vehicle.

### CROSS REFERENCE AND PRIORITY TO RELATED APPLICATIONS

This application claims the benefit of priority under 35 U.S.C. 119(e) to: U.S. Provisional No. 63/271,530 entitled “SYSTEM AND METHOD FOR HYPERLOOP STATE ESTIMATION OF MULTIPLE AXES,” filed on Oct. 25, 2021.

All the aforementioned applications are hereby incorporated by reference in their entirety.

### BACKGROUND

Hyperloop is a new mode of transportation relying on a hyperloop vehicle traveling through a tube having a near-vacuum environment. The projected velocity of the hyperloop vehicle may exceed 700 mph (1,127 km/h) in commercialized implementations. A hyperloop vehicle comprises a hyperloop bogie that may rely on many types of tracks for guidance, levitation, and/or propulsion. However, magnetic levitation (“maglev”) is generally favored over traditional wheeled implementations because maglev provides a substantially frictionless means of guidance, levitation, and propulsion. Having maglev coupled with near-vacuum environments provides for high, sustainable velocities of hyperloop vehicles moving through the tube. However, engineering challenges in maglev require new solutions.

While maglev is preferred for some implementations, maglev requires carefully calibrated interactions between the bogie and the track (or rails). Magnetic field interactions may be non-linear and may be difficult to calculate in a hyperloop environment due to a number of factors (e.g., the high velocity of the bogie). Therefore, determining the position and orientation of a maglev-based bogie is difficult even in ideal operating environment. Moreover, operating in emergencies is more difficult due to the problems that greatly affect the nominal use cases.

For example, maglev requires air gaps between the electromagnetic engine (or assemblies) and the track. In some implementations, the air gap may be as small as fifteen millimeters, which is roughly the thickness of fifteen credit cards stacked on one another. As the hyperloop vehicle travels along the track, the air gap may require such precise magnetic interactions that a human operator is simply incapable of responding quickly enough to avoid a collision between the electromagnetic engine and the track. Not knowing the position and orientation of the hyperloop vehicle at a later point in time can lead to outcomes where the hyperloop vehicle collides with an object, potentially resulting in the loss of property and even life.

As such, those skilled in the art are seeking solutions to effectively estimate, with reasonable certainty, the future state of a hyperloop vehicle while in flight. Such a state estimation provides for the safe and efficient operation of hyperloop vehicles.

### SUMMARY

A solution is disclosed for the generation of a state estimation for a hyperloop vehicle. The solution includes a state estimation system and a method. The solution comprises receiving, at a processor, first sensor data from a sensor system, wherein the sensor system comprises a laser-gap sensor and an inertial-measurement unit. The first sensor data comprises a first laser-based measurement and a first inertial-measurement-based measurement. The solution further generates, at the processor, a first position and a first orientation, wherein the first position and the first orientation are generated from the first sensor data. The solution further generates, at the processor, a predicted distance using a Kalman filter, wherein the predicted distance is measured between the hyperloop vehicle and a rail. The solution further generates, at the processor, a predicted orientation using the Kalman filter, wherein the predicted orientation is measured with respect to the hyperloop vehicle and the rail. The solution further sends, at the processor, the predicted position and the predicted orientation to a motion execution controller, wherein the motion execution controller is configured to command at least one engine of the hyperloop vehicle, wherein the commanding causes the hyperloop vehicle to move to the predicted position with the predicted orientation. The solution further comprises determining, at the processor, a noise value, wherein the noise value is associated with a sensor-related deviation, wherein the sensor-related deviation is accounted for by the Kalman filter prior to generating the predicted position, the predicted orientation, or a combination thereof. The solution further comprises calibrating, at the processor, the sensor system to generate a sensor calibration value, wherein the sensor-related deviation is based on the sensor calibration value. The solution further comprises measuring, at the processor, a track bias, wherein the track bias is measured by the laser gap sensor, wherein the track bias is accounted for by the Kalman filter prior to generating the predicted position, the predicted orientation, or a combination thereof. The track bias may be due to track tolerance, track material variation, track roughness, or a combination thereof. The solution further comprises detecting, at the processor, a longitudinal gap, wherein the longitudinal gap is measured by the laser gap sensor, wherein the longitudinal gap is accounted for by the Kalman filter prior to generating the predicted position, the predicted orientation, or a combination thereof. The solution further comprises detecting, at the processor, a potential fault, wherein the potential fault is accounted for by the Kalman filter prior to generating the predicted position, the predicted orientation, or a combination thereof. The potential fault may relate to measurement faults, state faults, whiteness of Kalman filter checking, or a combination thereof. The fault detecting may be based on measurement chi square tests, state chi square tests, measurement auto-correlation tests, measurement validity tests, minimum measurement tests, or a combination thereof.

### BRIEF DESCRIPTION OF DRAWINGS

The accompanying drawings, which are incorporated herein and constitute part of this specification, illustrate exemplary aspects of the claims, and together with the general description given above and the detailed description given below, serve to explain the features of the claims.

FIG. 1 is a block diagram illustrating a track assembly, as shown from a top perspective.

FIG. 2 is a block diagram illustrating a hyperloop vehicle, as shown from a top perspective.

FIG. 3 is a block diagram illustrating a state estimation system configured for a hyperloop vehicle.

FIG. 4A is a flowchart diagram illustrating a process for state estimation of a hyperloop vehicle.

FIG. 4B is a perspective view illustrating a hyperloop vehicle, as shown from a three-quarters perspective.

FIG. 4C is a perspective view illustrating a hyperloop vehicle, as shown from a three-quarters perspective.

FIG. 4D is a planar view illustrating a hyperloop vehicle, as shown from a top perspective.

FIG. 4E is a planar view illustrating a hyperloop vehicle, as shown from a top perspective.

FIG. 4F is a planar view illustrating a hyperloop vehicle, as shown from a rear perspective.

FIG. 4G is a flowchart illustrating a process for state estimation of a hyperloop vehicle.

FIG. 5 is a block diagram illustrating an example computing device suitable for use with the various aspects described herein.

FIG. 6 is a block diagram illustrating an example server suitable for use with the various aspects described herein.

### DETAILED DESCRIPTION

Various aspects will be described in detail with reference to the accompanying drawings. Wherever possible, the same reference numbers will be used throughout the drawings to refer to the same or like parts. References made to particular examples and implementations are for illustrative purposes, and are not intended to limit the scope of the claims.

A hyperloop vehicle is generally comprised of a hyperloop pod and a hyperloop bogie. Hyperloop pods may be attached to a bogie that has a plurality of electromagnetic engines (or assemblies) that provide guidance, levitation, and/or propulsion. Propulsion generally provides locomotion along the track in what one of skill in the art would consider the x-axis (or longitudinal direction of the track). Levitation and guidance generally provide calibration of the hyperloop vehicle in five axes viz. y, z, roll, pitch, and yaw such that the hyperloop vehicle may properly traverse along the track in the x-axis without collision between the hyperloop vehicle and the track. For example, if the nose of the hyperloop vehicle pitches too high, the electromagnetic engines may collide with the track, thus causing harm to property and passengers. Similarly, if the hyperloop vehicle rotates about the z-axis to an excessive degree, the hyperloop vehicle may collide with the tube itself, causing damage to property as well as loss of life.

Providing effective guidance, levitation, and propulsion is a non-trivial problem because a hyperloop vehicle may have a longitudinal size that requires several electromagnetic engines to operate in coordination in order to ensure the hyperloop bogie and the attached pod ride with the desired air gap (e.g., eight to thirty millimeters). In the event that one electromagnetic engine exhibits aberrant behavior, the remaining electromagnetic engines may need to compensate in order to sustain safe, efficient locomotion. While the various electromagnetic engines may be similarly designed, each may have a unique variance that also needs to be accounted for by a levitation and guidance algorithm designed to maintain a particular position and orientation during flight.

To further compound the problem of guidance, levitation, and propulsion control, magnetic fields and electromagnetic forces tend to have non-linear behavior that is highly dynamic. For instance, the flux density of a rail may be affected by the distance to the electromagnetic source (e.g., the electromagnetic engine/assembly), the velocity of the electromagnetic engine relative to the rail as well as the orientation of the electromagnetic source relative to the rail. In short, managing a plurality of electromagnetic engines with a small air gap requires a solution to ensure that electromagnetic interactions achieve the desired results without introducing undesired results.

Beyond maintaining a safe air gap, the hyperloop vehicle generally needs control while operating within the tube. Such control capabilities include accelerating, decelerating, turning, rolling, pitching, yawing, and similar operations that affect the position and/or orientation of the hyperloop vehicle. For example, a hyperloop vehicle typically travels through non-moving switches at intersections. Such non-moving switches require careful coordination among various electromagnetic assemblies (or engines) in order to traverse one plurality of rails to another plurality of rails. Failure to adequately do so can lead to catastrophic results (e.g., loss of life). Therefore, basic travel commands also require calibrated control of the position and orientation of the hyperloop vehicle.

Hyperloop is an incredibly fast mode of transportation. Having the combination of maglev and near-vacuum environments enables sustainable speeds that are unlike anything in existence. As such, algorithms and systems configured to prevent failures and ensure operations likewise need to execute quickly and efficiently. Long compute times can lead to instant catastrophes. Stated differently, onboard systems require both a rapid computation execution as well as near-instantaneous response by physical systems (e.g., electromagnetic coils). As such, an onboard state estimation system requires configurations that can meet the demands of high-speed, hyperloop-based travel.

A solution to the above-stated problems is a system and method for hyperloop vehicle guidance, levitation, and propulsion control that utilizes state estimation to provide position-, velocity-, and/or orientation-related information to a motion controller configured to manage a plurality of electromagnetic engines/assemblies disposed throughout the hyperloop vehicle (often in the bogie). The state of the hyperloop vehicle may be generally defined as the five-axis orientation (i.e., y, z, roll, pitch, yaw) of the hyperloop vehicle. Since the state of the hyperloop vehicle constantly changes, the motion controller may continuously update the commands sent to the electromagnetic guidance engines such that safe, efficient flight of the hyperloop vehicle is achieved as well as maintained during travel.

To determine the current state of the hyperloop vehicle, the disclosed solution relies on a number of sensors disposed throughout the hyperloop bogie and hyperloop pod. For instance, a plurality of inertial measurement units (“IMUs”) and a plurality of laser sensors may operate to determine the position and/or orientation (or state) of the bogie and pod. Further, a plurality of laser sensors may be utilized to measure distance as well as to determine orientation of the hyperloop vehicle. Further, the plurality of laser sensors may measure track deviations.

In sum, the disclosed solution enables a hyperloop vehicle to traverse longitudinally along a track without collision. Further, the disclosed solution enables more energy-efficient operation of the plurality of electromagnetic engines. Still further, the disclosed solution provides for smoother rides for passengers and cargo. Yet further, the disclosed solution provides for thermally efficient operation of the plurality of electromagnetic engines.

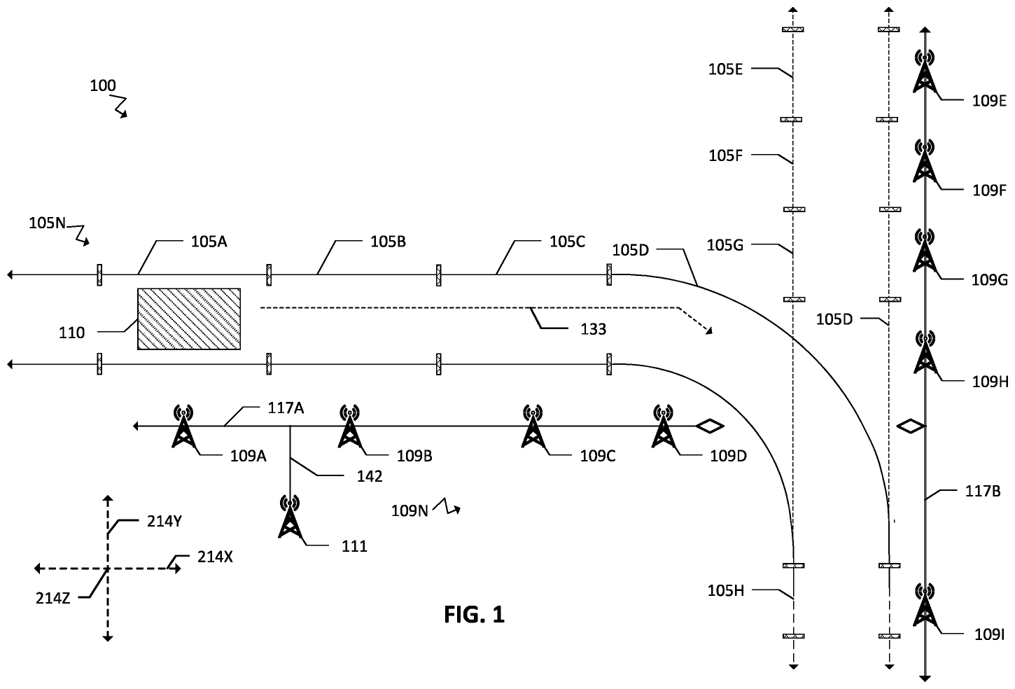

FIG. 1 illustrates a block diagram of a track assembly 100 with a hyperloop vehicle 110. A plurality of axes is shown to orient the reader viz. a first axis 214X, a second axis 214Y, and a third axis 214Z.

A plurality of tube sections 105N has a first tube section 105A, a second tube section 105B, a third tube section 105C, a fourth tube section 105D, a fifth tube section 105E, a sixth tube section 105F, a seventh tube section 105G, an eighth tube section 105H, and a ninth tube section 105I. The plurality of tube sections 105N are generally assembled together on the site of the track assembly 100. In one aspect, the plurality of tube sections 105N may be supported by pylons or other superstructures that elevate the tube above ground level. Such support structures are commonly referred to as “hyperstructure.” In another aspect, the plurality of tube sections 105N may have a near-vacuum environment such that the hyperloop vehicle 110 may operate with reduced air resistance. However, low air resistance enables high velocities that increase risk to passengers and/or cargo, hence the need for the disclosed solution.

The plurality of tube sections 105N has a track (not shown) disposed therein. In one aspect, the track may be made of laminated steel that is configured to enable maglev locomotion of the hyperloop vehicle 110. Other ferromagnetic materials may be similarly utilized.

The bogie assembly 220 possesses the necessary systems to provide locomotion that is safe, energy efficient, and reliable. For instance, the bogie assembly 220 may have propulsion systems that generate force by use of electromagnetic engines disposed near the rails of the track. The bogie assembly 220 may have additional systems including braking systems, levitation systems, guidance systems, lighting systems, sensor systems, fault tolerance systems, passenger management systems, cargo management systems, navigation systems, communication systems, emergency systems, maintenance systems, etc.

The hyperloop vehicle 110 comprises a pod assembly, that is configured to provide transportation of cargo, passengers, or a combination thereof. The pod assembly may have some of the systems of the bogie assembly (and vice versa). For the purposes of this disclosure, the hyperloop vehicle 110 will be generally referred to for both the bogie assembly and the pod assembly. One of skill in the art will appreciate that the internal configuration of the hyperloop vehicle 110 may vary depending on the operating environment of the hyperloop implementation.

A direction of travel 133 is shown to indicate the direction along which the hyperloop vehicle 110 is traveling. As shown, the hyperloop vehicle 110 is traveling along the axis 214X toward the tube section 105D at which point the hyperloop vehicle 110 will turn toward the section 105H. Thus, the direction of travel 133 transitions to become substantially parallel with the axis 214Y. The hyperloop vehicle 110 is configured to turn at high speeds; if a second hyperloop vehicle is traveling through the tube sections 105E, 105F, 105G, the hyperloop vehicle 110 may need to have such information in order to avoid a collision with the second hyperloop vehicle. The state estimation disclosed herein may anticipate a collision at a given time. In addition, the motion control provided herein may be utilized to avoid the collision based on the state estimation. Thus, a second hyperloop vehicle can be avoided with the aid of the disclosed solution.

A plurality of transponders 109N are disposed at or near the plurality of tube sections 105N. The plurality of transponders 109N comprises a first transponder 109A, a second transponder 109B, a third transponder 109C, a fourth transponder 109D, a fifth transponder 109E, a sixth transponder 109F, a seventh transponder 109G, an eighth transponder 109H, and a ninth transponder 109I. The transponders 109A, 109B, 109C, 109D are interconnected by a link 117A. The transponders 109E, 109F, 109G, 109H, 109I are connected via a link 117B. In one aspect, the links 117A, 117B may be connected such that the plurality of transponders 109N are interconnected and understood be one network (or subnetwork). For clarity, a diamond symbol is shown to depict that the links 117A, 117B are interconnected.

A transponder is generally configured to communicate with the hyperloop vehicle 110 when in proximity to the transponder. Information may be sent from the transponder to the hyperloop vehicle 110 or vice versa, depending on operating conditions and parameters. For instance, the hyperloop vehicle 110 is shown as passing the transponder 109A in the instant view. The hyperloop vehicle 110 will pass the transponder 109B when traveling through the tube section 105B. In one aspect, the plurality of transponders 109N may correspond to each of the plurality of tube sections 105N. For instance, the tube section 105A corresponds to the transponder 109A. In one aspect, the tube section 105A may have the transponder 109A attached thereto and deployed as part of the tube section 105A.

A high-speed network 111 is available at or near the track assembly 100 such that the elements within the track assembly 100 may communicate with other elements in the track assembly 100. The high-speed network 111 is connected to the plurality of transponders 109N via a link 142. In one aspect, the plurality of transponders 109N may provide access to information communicated by the high-speed network 111. The high-speed network 111 may be a combination of wired and wireless communication means, in one aspect. In one aspect, the high-speed network 111 may be 5G. In another aspect, the high-speed network 111 may be WIFI. In general, the hyperloop vehicle 110 may be in communication with the high-speed network 111 as well as the plurality of transponders 109N, wherein each communication means has an assigned role. For instance, the plurality of transponders 109N may be charged with delivering short, critical messages whereas the high-speed network 111 may be charged with delivering long, less-critical messages.

The hyperloop vehicle 110 may communicate with a fleet management center (not shown) via the high-speed network 111 in order to communicate fleet-management data. For example, a message may be sent to the hyperloop vehicle 110 to instruct the hyperloop vehicle 110 to enter a stable for service. Such messages provide yet another source of data for the disclosed solution to enable guidance control of the hyperloop vehicle 110. For instance, the hyperloop vehicle 110 may require messages to guide the hyperloop vehicle through a non-moving switch (e.g., at or near the tube section 105D).

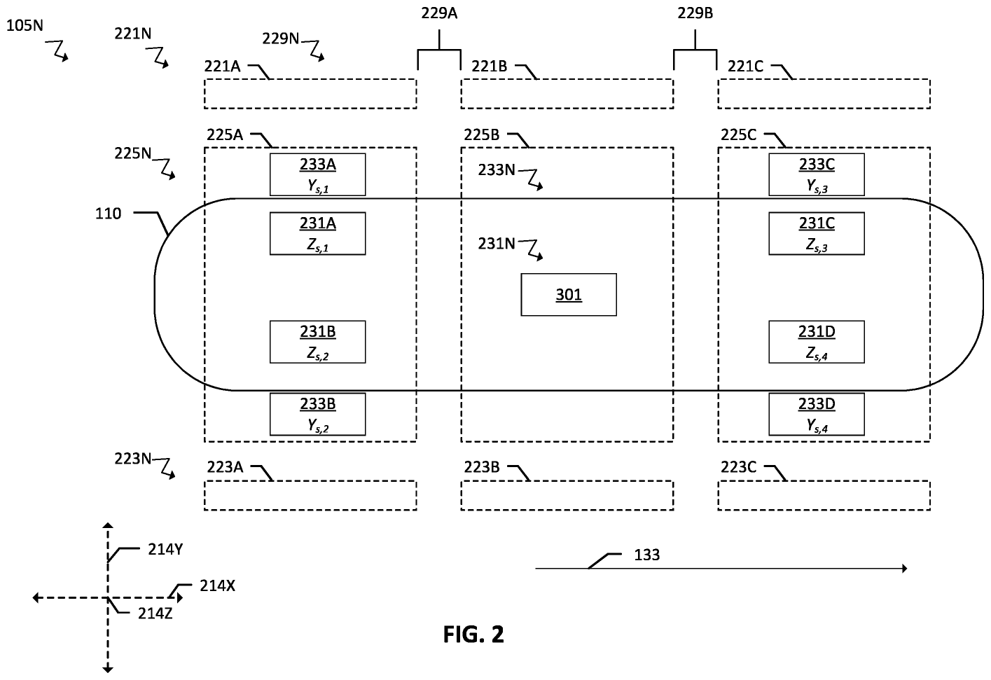

FIG. 2 is a block diagram illustrating the hyperloop vehicle 110, as shown from a top perspective. The hyperloop vehicle 110 is configured to utilize one or more laser sensors to measure the distance to levitation and guidance tracks (comprised of rails). One or more inertial motion units (“IMUs”) may be utilized to measure the translational acceleration and rotational velocities of the hyperloop vehicle 110. Laser sensors and the IMU may be fused to obtain richer data and estimates relating to the hyperloop vehicle 110, such as: the position, the velocity, the rate of velocity, the orientation, the rate of orientation at the center of gravity, bias of levitation track state, bias of guidance track state, or a combination thereof.

The hyperloop vehicle 110 is disposed in the plurality of rail sections 105N. The plurality of rail sections 105N has a first plurality of guidance rails 221N, a second plurality of guidance rails 223N, and a plurality of levitation rails 225N. The plurality of guidance rails 221N is comprised of a first guidance rail 221A, a second guidance rail 221B, and a third guidance rail 221C. The plurality of guidance rails 223N is comprised of a first guidance rail 223A, a second guidance rail 223B, and a third guidance rail 223C. The pluralities of guidance rails 221N, 223N are generally configured to provide five-degrees of control viz. the axis 214Y, the axis 214Z, roll, pitch, and yaw. One of skill in the art will appreciate that the axes 214Z, 214Y, 214Z disclosed herein may be relative to the track assembly 100 or the hyperloop vehicle 110 itself.

The plurality of levitation rails 225N is comprised of a first levitation rail 225A, a second levitation rail 225B, and a third levitation rail 225C. The plurality of levitation rails 225N are generally configured to provide levitation along the axis 214X (or longitudinally to the plurality of tube sections 105N) as the hyperloop vehicle 110 travels along the axis 214X.

A first plurality of laser sensors 231N is disposed on the hyperloop vehicle 110. The plurality of laser sensors 231N is comprised of a first laser sensor 231A (Z_{s,1}), a second laser sensor 231B (Z_{s,2}), a third laser sensor 231C (Z_{s,3}), and a fourth laser sensor 231D (Z_{s,4}). The plurality of laser sensors 231N is configured to measure the distance between the hyperloop vehicle 110 and the plurality of propulsion rails 225N.

A second plurality of laser sensors 233N is disposed on the hyperloop vehicle 110. The plurality of laser sensors 233N is comprised of a first laser sensor 233A (Y_{s,1}), a second laser sensor 233B (Y_{s,2}), a third laser sensor 233C (Y_{s,3}), and a fourth laser sensor 233D (Y_{s,4}). The plurality of laser sensors 233N are configured to measure the distance between the hyperloop vehicle 110 and the pluralities of guidance rails 221N, 223N.

One of skill in the art will appreciate that the pluralities of laser sensors 231N, 233N are merely illustrative. Many additional laser sensors and IMUs may be disposed on the body of the hyperloop vehicle 110. The placement may be on the pod, the bogie, or a combination thereof. Having multiple sensors at varying locations provides richer data for the disclosed state estimation system. For instance, the laser sensors 233A, 233C may be fused in order to provide more accurate (or richer) data regarding the position and/or orientation of the hyperloop vehicle 110.

A first gap 229A is formed by the distance between the rails 221A, 221B, 223A, 223B, 225A, 225B. A second gap 229B is formed by the distance between the rails 221B, 221C, 223B, 223C, 225B, 225C. A plurality of gaps 229N is formed by the gaps 229A, 229B. The plurality of gaps 229N may be due to a number of reasons. For example, the plurality of gaps 229N may be the result of installation tolerances being exceeded during deployment of the track assembly 100. Other causes for the plurality of gaps 229N include: seismic activity, metal fatigue, inaccurate specifications, mechanical damage, melting, high-speed contact, debris, etc. The pluralities of laser sensors 231N, 233N are configured to detect the gaps 229A, 229B in order for the state estimation to be determined. Further, the pluralities of laser sensors 231N, 233N may be configured to detect faults (such as the plurality of gaps 229N) as an added benefit of performing state estimation.

A state estimation system 301 is disposed on the hyperloop vehicle 110. The state estimation system 301 is generally configured to generate a state estimation based on information from sensors (e.g., the pluralities of laser sensors 231N, 233N) onboard the hyperloop vehicle 110.

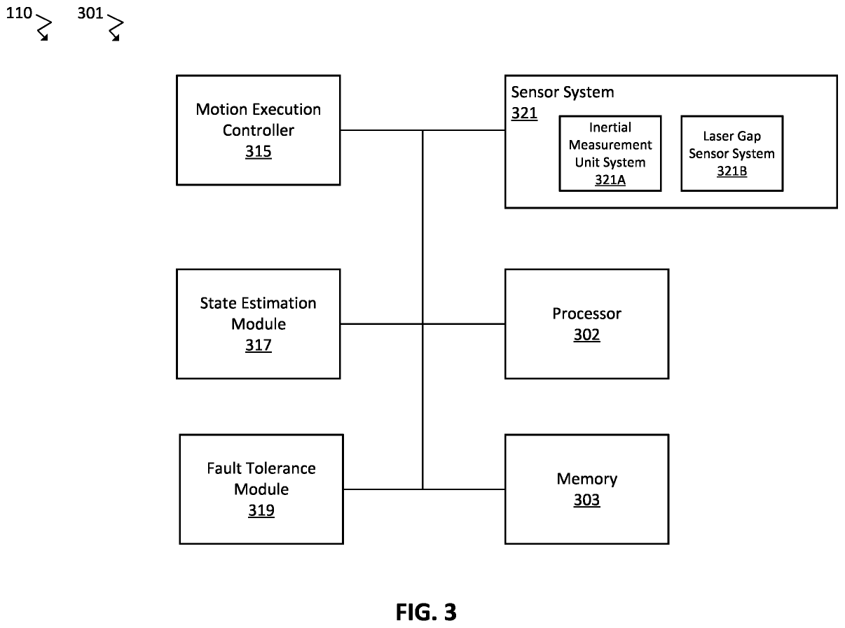

FIG. 3 is a block diagram illustrating the state estimation system 301 configured for the hyperloop vehicle 110. The state estimation system 301 comprises a motion execution controller 315, a state estimation module 317, a fault tolerance module 319, a sensor system 321, a processor 302, and a memory 303.

The motion execution controller 315 is generally configured to generate commands for electromagnetic engines that provide guidance, levitation, and/or propulsion for the hyperloop vehicle 110. Examples of commands include: voltage values, current values, air gap values, force values, etc. Given that electromagnetic forces may be non-linear, the motion execution controller 315 is configured to perform linearization of values in order to send commands to the electromagnetic engines. In one aspect, the motion execution controller 315 is configured to report faults to the fault tolerance module 319 in order to inform state-estimation-related operations.

The state estimation module 317 is generally configured to generate a state estimation that represents a future orientation (i.e., roll, pitch, and yaw), a position (e.g., a fixed position as measured by the axes 214X, 214Y, 214Z), the rate of orientation (e.g., angular velocity), and/or the rate of position (e.g., linear velocity). For example, the axes 214X, 214Y, 214Z may be utilized to determine the absolute position of the hyperloop vehicle 110 with respect to a fixed and/or relative position. Likewise, the roll, pitch, and yaw may be represented as rotational values about a fixed axis associated with the hyperloop vehicle 110. For example, the roll, pitch, and yaw may be measured in radian and/or degrees about the axes 214X, 214Y, 214Z which extend from the center of gravity of the hyperloop vehicle 110.

The fault tolerance module 319 is generally configured to address fault conditions that occur within the hyperloop vehicle 110. For example, a state estimation may indicate that a collision is imminent. Another example may be where state estimation detects a sensor failure. For instance, the state estimation may account for the failure of the sensor system 321 such that other sensor systems may be utilized. Still another example may be where state estimation detects an engine failure. As such, the fault tolerance module 321 may invoke an emergency command that averts a collision (e.g., a command to apply braking force to the hyperloop vehicle 110).

The sensor system 321 is generally configured to provide sensor data to the state estimation system 301. The sensor system 321 comprises an inertial measurement unit (“IMU”) system 321A and a laser gap sensor system 321B.

The IMU 321A is configured to provide measurements of linear acceleration and angular velocities. The laser gap sensor system 321B and the IMU 321A may coordinate to determine the position and/or orientation of the hyperloop vehicle 110. In one configuration, the laser gap sensor system 321B is configured to provide more accurate measurements in order to measure the fast dynamics of the hyperloop vehicle 110. In contrast, the IMU 321A is configured to provide more details about the position and orientation of the hyperloop vehicle 110; however, such details may be at longer intervals between measurements than those provided by the laser gap sensor system 321B. As such, fusing the laser-based measurements with the IMU-based measurements provides a richer representation of the state of the hyperloop vehicle 110. One of skill in the art will appreciate that more laser sensors and/or IMUs may be disposed throughout the hyperloop vehicle 110 in order to increase the number of measurements obtained, thus increasing accuracy, redundancy, etc.

The laser gap sensor system 321B is generally configured to provide laser gap measurements between the hyperloop vehicle 110 and the track assembly 100, the pluralities of guidance rails 221N, 223N, the plurality of levitation rails 225N, and other objects. The laser gap sensor system 321 comprises the pluralities of laser sensors 231N, 223N.

The processor 302 may be a shared processor which is utilized by other systems, modules, etc. within the disclosed solution. For example, the processor 302 may be configured as a general-purpose processor (e.g., x86, ARM, etc.) that is configured to manage operations from many disparate systems, including the state estimation system 301. In another aspect, the processor 302 may be an abstraction because any of the modules, systems, and/or components disclosed herein may have a local processor (or controller) that handles aspects of the state estimation system 301 (e.g., ASICs, FPGAs, etc.).

The memory 303 is generally configured to store and retrieve information. The memory 303 may be comprised of volatile memory, non-volatile memory, or a combination thereof. The memory 303 may be closely coupled to the processor 302, in one aspect. For example, the memory 303 may be a cache that is co-located with the processor 302. As with the processor 302, the memory 303 may, in one aspect, be an abstraction wherein the modules, systems, and/or components each have a memory that acts in concert across the state estimation system 301.

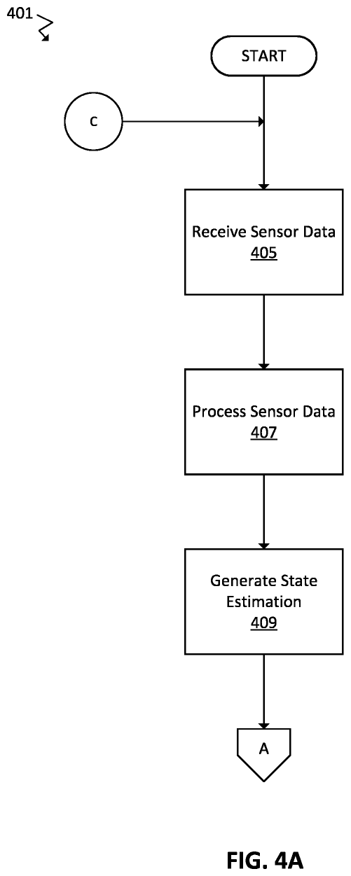

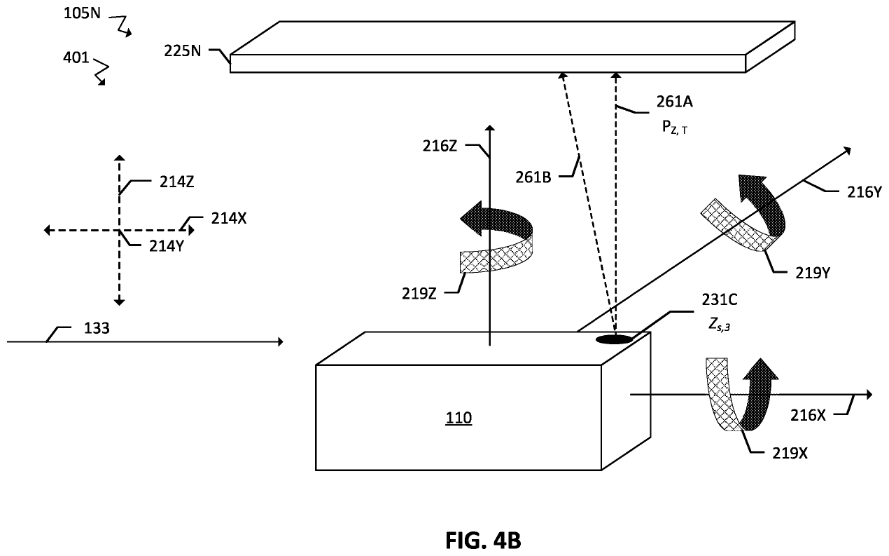

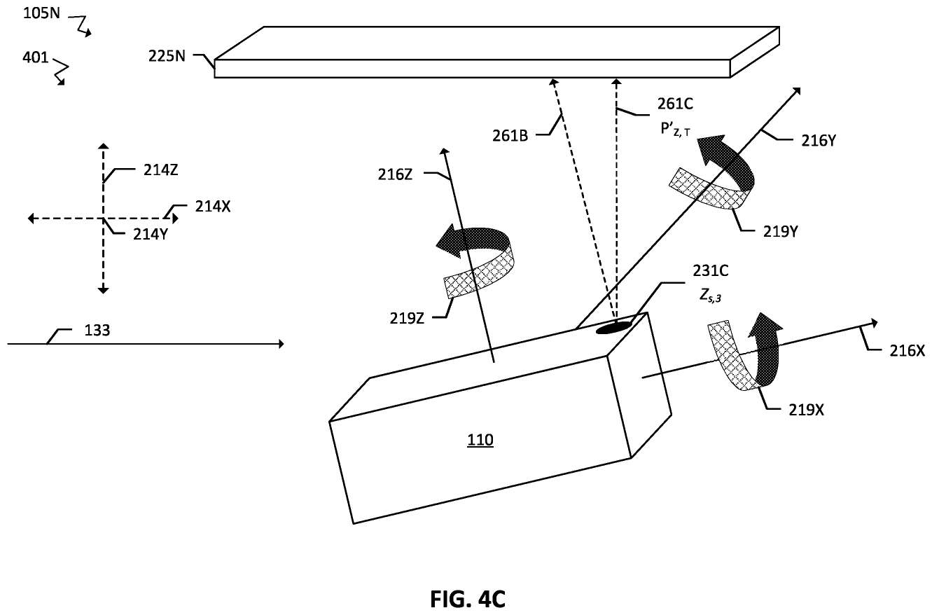

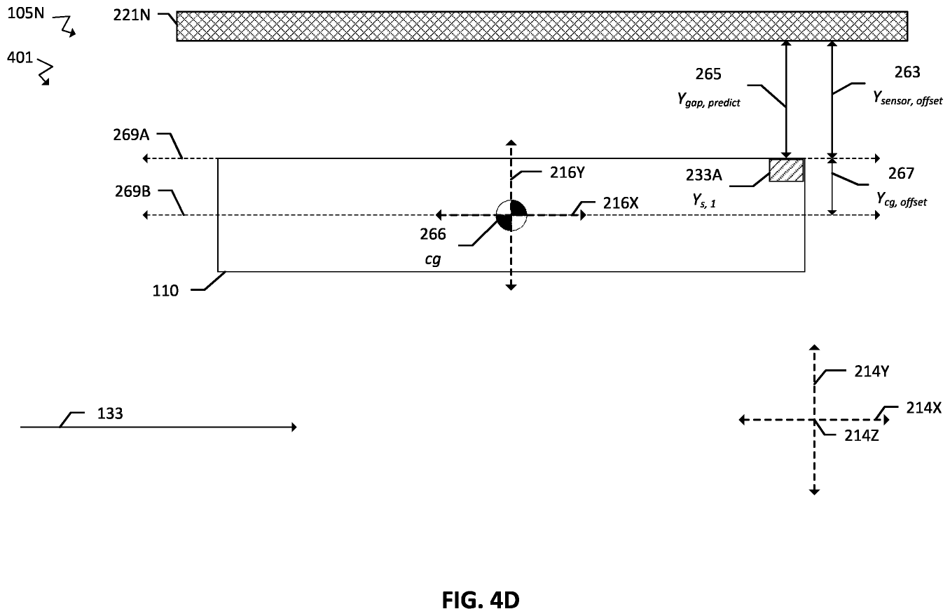

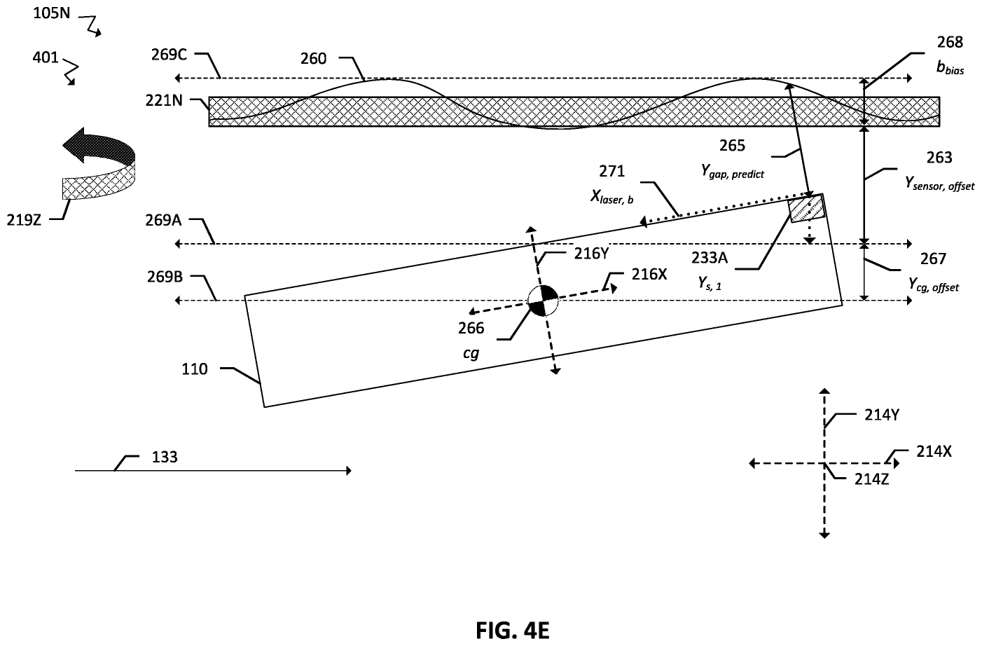

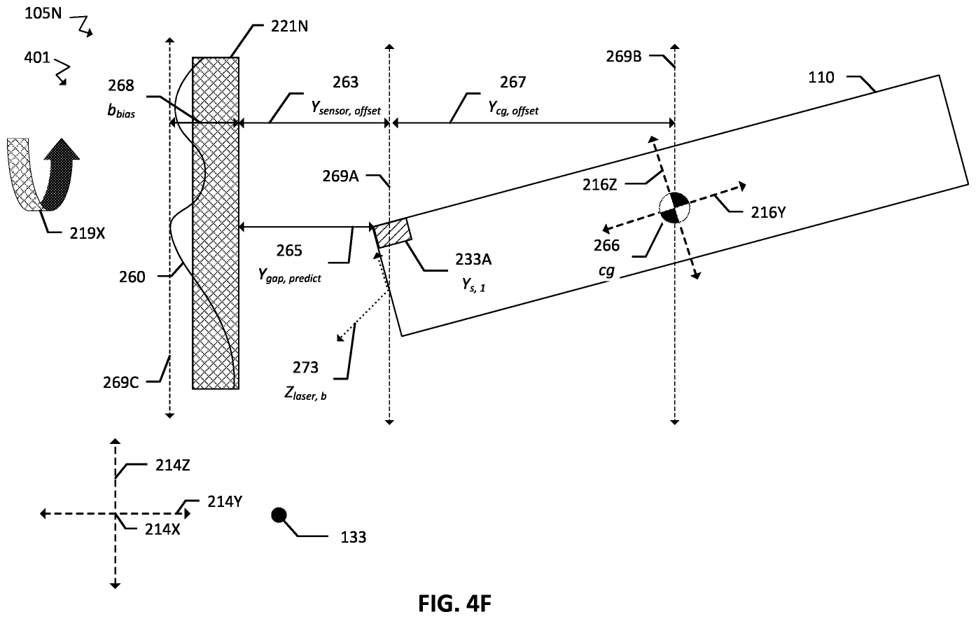

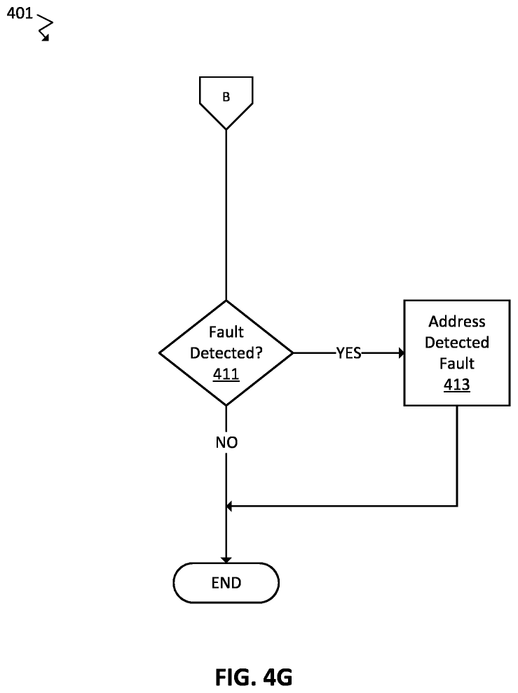

FIG. 4A is a flowchart diagram illustrating a process 401 for state estimation of the hyperloop vehicle 110. The process 401 is generally configured to generate a state estimation using the state estimation system 301 from FIG. 3 above. The process 401 begins at the start block and proceeds to the block 405.

At the block 405, the process 401 receives sensor data. The sensor data is processed by the sensor system 321 such that the state estimation may be generated by the process 401 at a subsequent operation. For example, the sensor system 321 may receive laser gap measurement values from the laser gap sensor system 321B. For example, such measurements may be the plurality of gaps 229N such that the electromagnetic engines may be commanded such that collision between the rail (e.g., the levitation rail 225A) and the electromagnetic engine is avoided. Other obtained sensor data may include data provided by the IMU 321A. The process 401 then proceeds to the block 407.

At the block 407, the process 401 processes the sensor data. The process 401 may fuse together laser-based measurements with inertial-related measurements. Laser-based measurements generally provide geometric information (e.g., the distance of the air gap between the guidance rail 221A and the hyperloop vehicle 110). The IMU system 321A provides measurements to measure linear acceleration and angular velocities. In one aspect, the laser-gap sensor system 321B may provide more accurate measurements for the fast dynamics of the hyperloop vehicle 110. Further, the IMU system 321A provides more details about the position and/or orientation of the hyperloop vehicle 110; however, such details may be at longer intervals between measurements than those provided by the laser-gap sensor system 321B. As such, fusing the laser-based measurements with the IMU-based measurements provides a richer representation of the state of the hyperloop vehicle 110 for use by the process 401. The process 401 then proceeds to the block 409.

At the block 409, the process 401 generates a state estimation. The generation of the state estimation will be illustrated by use of FIG. 4B through FIG. 4F that demonstrate the application of a Kalman-filter-based state estimation generation. The Kalman filter is utilized to provide accurate estimation of the position and/or orientation of the hyperloop vehicle 110. The Kalman filter may, in one configuration, be a linear Kalman filter. The Kalman filter is generally configured to obtain measurements from the pluralities of laser sensors 231N, 233N as well as the IMU 321A (e.g., via the sensor system 321) in order to generate a state estimation that relates to y, z, roll, pitch, yaw, rate of y, rate of z, rate of roll, rate of pitch, and rate of yaw (of the hyperloop vehicle 110) as well as four track bias states (b₁, b₂, b₃, and b₄, shown below). The bias states are configured to being estimated in real-time to augment the pose estimates. The states of the hyperloop vehicle 110 are shown in Formula 1 below.

$$States of the Hyperloop Vehicle ,$$

$$x = [ \begin{matrix}y \\ z \\ φ \\ θ \\ ψ \\ \dot{y} \\ \dot{z} \\ \dot{φ} \\ \dot{θ} \\ \dot{ψ} \\ {b}_{1} \\ {b}_{2} \\ {b}_{3} \\ {b}_{4}\end{matrix} ] \qquad Formula 1$$

where y, z, φ, θ, ψ, \dot{y}, ż, \dot{φ}, \dot{θ}, and \dot{ψ}, are the y position, z position, roll, pitch, yaw, y velocity, z velocity, roll rate, pitch rate, and yaw rate of the hyperloop vehicle 110 at a center of gravity of the hyperloop vehicle 110, further where b₁, b₂, b₃, and b₄ are track bias error states.

A linearization algorithm is configured to eliminate the non-linear effects such that the commanded force from the motion execution controller 315 results in the corresponding force acting on the center of gravity of the hyperloop vehicle 110. As such, the dynamic behavior of the hyperloop vehicle 110 is equivalent to five, decoupled axes (i.e., a plurality of decoupled axes), with each one modeled as a free-floating mass value. Such a result provides the state space equation shown in Formula 2 below.

$$Space State Equation ,$$

$$\dot{x} = {\underbrace{[ \begin{matrix}0 & I & 0 \\ 0 & 0 & 0\end{matrix} ]}}_{A} x + {\underbrace{[ \begin{matrix}0 & 0 & 0 & 0 & 0 \\ ⋮ & ⋮ & ⋮ & ⋮ & ⋮ \\ 0 & 0 & 0 & 0 & 0 \\ \frac{1}{m} & 0 & 0 & 0 & 0 \\ 0 & \frac{1}{m} & 0 & 0 & 0 \\ 0 & 0 & \frac{1}{{J}_{x}} & 0 & 0 \\ 0 & 0 & 0 & \frac{1}{{J}_{y}} & 0 \\ 0 & 0 & 0 & 0 & \frac{1}{{J}_{z}} \\ 0 & 0 & 0 & 0 & 0 \\ 0 & 0 & 0 & 0 & 0 \\ 0 & 0 & 0 & 0 & 0\end{matrix} ]}}_{B} [ \begin{matrix}{F}_{y} \\ {F}_{Z} \\ {M}_{x} \\ {M}_{y} \\ {M}_{z}\end{matrix} ] + {\underbrace{[ \begin{matrix}0 & 0 & 0 & 0 & 0 \\ ⋮ & ⋮ & ⋮ & ⋮ & ⋮ \\ 0 & 0 & 0 & 0 & 0 \\ \frac{1}{m} & 0 & 0 & 0 & 0 \\ 0 & \frac{1}{m} & 0 & 0 & 0 \\ 0 & 0 & \frac{1}{{J}_{x}} & 0 & 0 \\ 0 & 0 & 0 & \frac{1}{{J}_{y}} & 0 \\ 0 & 0 & 0 & 0 & \frac{1}{{J}_{z}} \\ 0 & 0 & 0 & 0 & 0 \\ 0 & 0 & 0 & 0 & 0 \\ 0 & 0 & 0 & 0 & 0\end{matrix} ]}}_{B} [ \begin{matrix}{w}_{y} \\ {w}_{z} \\ {w}_{φ} \\ {w}_{θ} \\ {w}_{ψ}\end{matrix} ] \qquad Formula 2$$

where F_{y}, F_{z}, Mₓ, M_{y}, and M_{z} are the forces and moments acting on the center of gravity of the hyperloop vehicle 110.

In Formula 2 above, w_{y}, w_{z}, w_{φ}, w_{θ}, and w_{ψ} may be the input noise. Such inputs encompass the random and unmodeled variation in the input force which can come from influences such as track tolerance, track material variation, track roughness, electromagnetic interference (“EMI”), or a combination thereof.

In addition to the state space equation of Formula 2 above, the measurements are modeled as shown in Formula 3 below.

$$Space State Measurements ,$$

$${y}^{*} = [ \begin{matrix}{y}_{m} \\ {z}_{m} \\ \int {\ddot{x}}_{m} dt \\ \int {\ddot{y}}_{m} dt \\ \int {\ddot{z}}_{m} dt \\ {\dot{φ}}_{m} \\ {\dot{θ}}_{m} \\ {\dot{ψ}}_{m}\end{matrix} ] = Cx \qquad Formula 3$$

$${y}_{m} = {[ {y}_{1} … {y}_{{N}_{y}} ]}^{T}$$

$${z}_{m} = {[ {z}_{1} … {z}_{{N}_{z}} ]}^{T}$$

$${\ddot{x}}_{m} = {[ {\ddot{x}}_{1} … {\ddot{x}}_{{N}_{IMU}} ]}^{T}$$

$${\ddot{y}}_{m} = {[ {\ddot{y}}_{1} … {\ddot{y}}_{{N}_{IMU}} ]}^{T}$$

$${\ddot{z}}_{m} = {[ {\ddot{z}}_{1} … {\ddot{z}}_{{N}_{IMU}} ]}^{T}$$

$${\dot{φ}}_{m} = {[ {\dot{φ}}_{1} … {\dot{φ}}_{{N}_{IMU}} ]}^{T}$$

$${\dot{θ}}_{m} = {[ {\dot{θ}}_{1} … {\dot{θ}}_{{N}_{IMU}} ]}^{T}$$

$${\dot{ψ}}_{m} = {[ {\dot{ψ}}_{1} … {\dot{ψ}}_{{N}_{IMU}} ]}^{T}$$

where C transforms the states to sensor values, y* is a vector of sensor values, the subscript m indicates a measured value.

As shown in Formula 3 above, yₘ and zₘ are the laser measurements of relative distance between (1) the track (e.g., the plurality of guidance rails 221N) and (2) the guidance and levitation plane, respectively. N_{y} and N_{z} indicate the total number of y-direction and z-direction laser sensors, respectively. ∫\ddot{x}ₘ dt, ∫ÿₘ dt, and ∫\ddot{z}ₘ dt are the calculated translational velocities which are generated by integrating the measured translational accelerations. Further, \dot{φ}ₘ, \dot{θ}ₘ, and \dot{ψ}ₘ are the measured angular velocities. N_{IMU} indicates the total number of IMUs.

One of skill in the art will appreciate that more than the single IMU 321A, as illustrated, may be disposed throughout the hyperloop vehicle 110. In general, more sensors provide more data but may increase costs, increase power consumption, be overly redundant, etc. Nevertheless, varying numbers of IMUs and laser sensors may be disposed throughout the exterior of the hyperloop vehicle 110. One of skill in the art will appreciate that integrated translation accelerations and measured angular velocities were properly filtered in order to reduce effects relating to bias, scale factor, calibration parameters, or a combination thereof. One of skill in the art will further appreciate that multiple IMUs (beyond the IMU 321A) may be used to reduce uncertainty in the Kalman filter.

The state space equations of Formula 3 may then be discretized for the Kalman filter. The state space equations of Formula 3 are discretized as shown in Formula 4 below.

$$Discretized Space State Equations$$

$${A}_{d} = {e}^{{AT}_{s}} = [ \begin{matrix}I & {IT}_{s} \\ 0 & I\end{matrix} ] \qquad Formula 4$$

$${B}_{d} = {BT}_{s}$$

$$H = C$$

The Kalman filter may be then applied as shown in Formula 5 below. One of skill in the art will appreciate that different implementations of the Kalman filter may be used for improved stability, improved computational efficiency, reduced power consumption, etc.

$$Applied Kalman Filter$$

$${[ \begin{matrix}\hat{x} \\ \hat{\dot{x}}\end{matrix} ]}_{k \vert k - 1} = {{A}_{d} [ \begin{matrix}\hat{x} \\ \hat{\dot{x}}\end{matrix} ]}_{k - 1 \vert k - 1} + {B}_{d} {u}_{k} \qquad Formula 5$$

$${P}_{k \vert k - 1} = {A}_{d} {P}_{k - 1 \vert k - 1} {A}_{d} + Q$$

$${K}_{k} = {P}_{k \vert k - 1} {{H}^{T} ( {HP}_{k \vert k - 1} {H}^{T} + R )}^{- 1}$$

$${[ \begin{matrix}\hat{x} \\ \hat{\dot{x}}\end{matrix} ]}_{k \vert k} = {[ \begin{matrix}\hat{x} \\ \hat{\dot{x}}\end{matrix} ]}_{k \vert k - 1} + {K}_{k} ( {y}_{k}^{*} - {H [ \begin{matrix}\hat{x} \\ \hat{\dot{x}}\end{matrix} ]}_{k \vert k - 1} )$$

$${P}_{k \vert k} = {P}_{k \vert k - 1} - {K}_{k} {HP}_{k \vert k - 1}$$

FIG. 4B is a perspective view illustrating the hyperloop vehicle 110, as shown from a three-quarters perspective. The hyperloop vehicle 110 has a plurality of axes projecting from the center of the hyperloop vehicle 110 viz. a first axis 216X, a second axis 216Y, and a third axis 216Z. Roll is depicted by an arrow 219X. Pitch is depicted by an arrow 219Y. Yaw is depicted by an arrow 219Z. The laser sensor 231C is configured to determine a vector 261A (P_{z,t}) in order to provide a state estimate. A vector 261B is measured at a tilted angle such as shown in FIG. 4C. As shown, the tilted angle is inferred by the vectors 261A, 261B.

FIG. 4C is a perspective view illustrating the hyperloop vehicle 110, as shown from a three-quarters perspective. In the instant view, the hyperloop vehicle 110 is pitched upward, with the nose of the hyperloop vehicle 110 approaching the plurality of propulsion rails 225N.

The Kalman filter may then be applied to translate the state of the hyperloop vehicle 110 with respect to the laser measurements. A vector 261C is shown as a subsequent measurement of the vector 261A from FIG. 4B above. When the hyperloop vehicle 110 is tilted, the angle between the vectors 261B, 261C may then be recalculated. Such recalculation provides information sufficient to fuse together in order to determine pitch and roll.

Laser measurements use the frame of the hyperloop vehicle 110 as a point of reference viz. the axes 216X, 216Y, 216Z. Therefore, to determine H matrix, a calculation is performed based on the laser sensor location (i.e., the laser sensor 231C) from bogie (local) frame of the hyperloop vehicle 110 to the track (global) frame (e.g., the plurality of levitation rails 225N and/or the pluralities of guidance rails 221N, 223N). Such a calculation is shown in Formula 6 below.

$$H Matrix Calculation .$$

$$\begin{matrix}[ \begin{matrix}{P}_{{x}_{T}} \\ {P}_{{y}_{T}} \\ {P}_{{z}_{T}}\end{matrix} ] = {[ [ \begin{matrix}1 & 0 & 0 \\ 0 & cos ( ϕ ) & sin ( ϕ ) \\ 0 & - sin ( ϕ ) & cos ( ϕ )\end{matrix} ] [ \begin{matrix}cos ( θ ) & 0 & sin ( θ ) \\ 0 & 1 & 0 \\ sin ( θ ) & 0 & cos ( θ )\end{matrix} ] [ \begin{matrix}cos ( ψ ) & sin ( ψ ) & 0 \\ - sin ( ψ ) & cos ( ψ ) & 0 \\ 0 & 0 & 1\end{matrix} ] ]}^{T} \\ [ \begin{matrix}{P}_{{x}_{B}} \\ {P}_{{y}_{B}} \\ {P}_{{z}_{B}}\end{matrix} ] \\ = [ \begin{matrix}cos ( θ ) cos ( ψ ) & - cos ( θ ) sin ( ψ ) & sin ( θ ) \\ \begin{matrix}sin ( ϕ ) sin ( θ ) cos ( ψ ) + \\ cos ( ϕ ) sin ( ψ )\end{matrix} & \begin{matrix}- sin ( ϕ ) sin ( θ ) sin ( ψ ) + \\ cos ( ϕ ) sin ( ψ )\end{matrix} & - sin ( ϕ ) cos ( θ ) \\ \begin{matrix}- cos ( ϕ ) sin ( θ ) cos ( ψ ) + \\ sin ( ϕ ) sin ( ψ )\end{matrix} & \begin{matrix}cos ( ϕ ) sin ( θ ) sin ( ψ ) + \\ sin ( ϕ ) cos ( θ )\end{matrix} & cos ( ϕ ) cos ( θ )\end{matrix} ] \cdot [ \begin{matrix}{P}_{{x}_{B}} \\ {P}_{{y}_{B}} \\ {P}_{{z}_{B}}\end{matrix} ] \\ \approx [ \begin{matrix}1 & - ψ & θ \\ ψ & 1 & - ϕ \\ - θ & ϕ & 1\end{matrix} ] [ \begin{matrix}{P}_{{x}_{B}} \\ {P}_{{y}_{B}} \\ {P}_{{z}_{B}}\end{matrix} ] ( with small angle approximation )\end{matrix} \qquad Formula 6$$

where ϕ, θ, ψ are the rotation angles for x, y and z axes, and [Pₓ_{_{B}}, P_{y}_{_{B}}, P_{z}_{_{B}}], [Pₓ_{_{T}}, P_{y}_{_{T}}, P_{z}_{_{T}}] are the laser location on bogie and track frame, respectively.

To determine the H matrix of Formula 6 above as well as to translate states to sensor values, the following assumption is applied: the angular movement of the hyperloop vehicle 110 is small such that the measurements of laser sensors pointing in the z-direction (e.g., along the axis 216Z) will be affected by the movements in the z-direction (e.g., along the axis 216Z) and rotation along the roll 219X direction and the pitch 219Y direction. Also, small angle approximations are applied when translating states to sensor values.

FIG. 4D is a planar view illustrating the hyperloop vehicle 110, as shown from a top perspective. The instant figure shows an example of how the y state is translated to one y sensor measurement. A center of gravity 266 is positioned on the hyperloop vehicle 110 for reference to the reader. A first axis 269A is substantially aligned with the plane of the hyperloop vehicle 110 that is substantially parallel to the plurality of rail sections 221N. A second axis 269B is substantially aligned with the axis 216X and the center of gravity 266.

The laser sensor 233A is configured to measure along a vector 265 (Y_{gap, predict}). Other laser sensors (not shown) may be similarly projected about the frame of the hyperloop vehicle 110 along the various axes 216X, 216Y, 216Z. As such, multiple measurements may be obtained and fused together in order to increase reliability, accuracy, etc. A vector 263 (Y_{sensor, offset}) and a vector 267 (Y_{eg, offset}) may then be determined from such laser-based measurements and the geometric information of the bogie assembly of the hyperloop vehicle 110.

FIG. 4E is a planar view illustrating the hyperloop vehicle 110, as shown from a top perspective. As shown, the hyperloop vehicle 110 is moving in the yaw 219Z direction such that the hyperloop vehicle 110 is approaching the plurality of guidance rails 221N. A curve 260 shows the subtle variation in the plurality of guidance rails 221N. For illustrative purposes, the vector 265 is in contact with the curve 260 to logically show that the bias of the plurality of guidance rails 221N is affecting the measured distance. A bias vector 268 (b_{bias}) is demarcated by the end of the vector 263 and an axis 269C. Further, the bias vector 268 (b_{bias}) is utilized to predict laser gap measurement(s) in Formula 8 above.

FIG. 4F is a planar view illustrating the hyperloop vehicle 110, as shown from a rear perspective. As shown, the hyperloop vehicle 110 is rotating in the roll 219X direction. Assuming only an offset in y-direction, the laser measurement prediction can be calculated as shown in Formula 7 below.

y_{gap}_{_{predict}}=−yₛₑₙ_{_{offset}}+y_cg_{offset} Formula 7: Laser Measurement Prediction,
where yₛₑₙ_{_{offset}} is the sensor location with respect to the track (e.g., the plurality of guidance rails 221N, 223N) in perfect states and y_cg_{offset} is the cg, of the hyperloop vehicle 110, as offset in the y direction (e.g., along the axis 216Y).

In addition, angle rotation in the yaw 219Z direction and the roll 219X direction would also introduce y_{gap} change, as shown in FIG. 4E and FIG. 4F. A vector 271 (X_{laser, b}) and a vector 273 (Z_{laser, b}) may be determined by geographic information of the bogie assembly of the hyperloop vehicle 110. Further, when rotation exists in yaw 219Z direction and roll 219X direction, y_{gap} can be described as shown in Formula 8 as well.

y_{gap}_{_{predict}}=−yₛₑₙ_{_{offset}}+y_{cg}_{_{offset}}−xₗₐₛₑᵣ_{_{b}}*sin(yaw)−Zₗₐₛₑᵣ_{_{b}}*sin(roll)+b_{bias}≈−yₛₑₙ_{_{offset}}+y_{cg}_{_{offset}}−Xₗₐₛₑᵣ_{_{b}}*yaw−Zₗₐₛₑᵣ_{_{b}}*roll+b_{bias} Formula 8: y_{gap}_{_{predict}} Determination,
where b_{bias} reflects the real-world variation of the track which is substantially but not actually flat, further b_{bias} is derived from b₁, b₂, b₃, and b₄ found in Formula 1 above.

One of skill in the art will appreciate that variations in the track may be estimated in stochastic models that result in a bounded error in the pose estimate calculations. Therefore, to translate state x to y-laser-sensor measurement, the first row of the H matrix for the y sensor may be represented by Formula 9 below.

H(1,:)=(1,0,−z_{loc},0,−x_{loc},0,0, . . . ,0) Formula 9: H Determination

Formula 9 shows no track bias states are associated with the first measurement. One of skill in the art will appreciate that the measurement modeling can result in a different H matrix formulation to give less-biased state estimations.

The output of the Kalman filter that is used for feedback control is the predicted states [\hat{x}]_{k|k}^{T}, which is a combination of the prediction of a process model and a feedback signal yₖ^{*}. The Kalman filter is configured to correct the prediction based upon the error between the measurement and the predicted states. To what extent the Kalman filter corrects this error is based upon the process noise covariance matrix, Q, and the measurement noise covariance matrix, R. A noisy model results in a large Q matrix, which causes the Kalman filter to trust the measurements yₖ^{*} more. In contrast, noisy feedback signals will result in a large R matrix, which causes the Kalman filter to trust the model outputs [\hat{x}]_{k|k-1}^{T} more. As a result, one of the most difficult problems in designing the Kalman filter is determining the Q and R matrices.

In order to accurately determine the Q and R matrices, one must consider the noise in the process of the dynamics and the sensor noise characteristics, respectively. With regard to the R matrix, the sensors are assumed to be laser sensors (e.g., the laser sensor 233A) that measure the respective gap of the laser sensor. The laser-sensor-based and IMU-based measurements can be characterized as being independent of each other with proper care. Furthermore, the measurement noise can be modeled as zero mean and Gaussian noise. As a result, the R matrix is a diagonal matrix with the diagonal terms corresponding to the variance of each of the sensors as shown in Formula 10 below. The noise of the IMU 321A may also be included when the IMU measurements are used. One of skill in the art will appreciate that the measurement noise covariance of the IMU in R can be modeled differently depending on the grade-level of the implemented IMU.

$$R Matrix Determination$$

$$R = [ \begin{matrix}{σ}_{s , 1}^{2} & … & 0 \\ ⋮ & ⋱ & ⋮ \\ 0 & … & {σ}_{s , N}\end{matrix} ] \qquad Formula 10$$

The variances can be found by first recording the sensor measurements when the hyperloop vehicle 110 is static (as a calibrating operation). Then, the standard deviation of these stationary measurement signals, and subsequently the variance, may be obtained from the sensor measurements in this static state. In order to find the Q matrix, the process noise may be considered, including the resulting influence on the states. The discrete state space equation is more accurately modeled as shown in Formula 11 below.

$$Discrete State Space Equation$$

$${x}_{k} = [ \begin{matrix}I & {IT}_{s} \\ 0 & I\end{matrix} ] {x}_{k - 1} + {\int }_{0}^{{T}_{s}} [ \begin{matrix}I & I ( {T}_{s} - τ ) \\ 0 & I\end{matrix} ] Bu ( τ ) d τ + {\int }_{0}^{{T}_{s}} [ \begin{matrix}I & I ( {T}_{s} - τ ) \\ 0 & I\end{matrix} ] Bw ( τ ) d τ \qquad Formula 11$$

$${x}_{k} = {A}_{d} {x}_{k - 1} + {F}_{d} + {\underbrace{{\int }_{0}^{{T}_{s}} [ \begin{matrix}I ( {T}_{s} - τ ) \\ I\end{matrix} ] \tilde{w} ( τ ) d τ}}_{{w}_{d}}$$

Since the first two terms on the right-hand side are captured by the Kalman filter process model, the noise created by the third term will determine size and structure of the Q matrix. The input matrix may be multiplied with the noise vector w(τ). The physical interpretation is such that the unmodeled noise in the force input of the hyperloop vehicle 110 will lead to variations in position and velocity of the hyperloop vehicle 110. Such a result may be interpreted as unmodeled phenomena that leads to unmodeled force variations which are Gaussian in nature. Based on this noise model, the Q matrix can be determined as shown in Formula 12 below. Further, Q_{track} may be used to account for variation in the track. Still further, Qₜₒₜₐₗ is the final process error covariance matrix in the Kalman filter.

$$Q Matrix Determination ,$$

$$\begin{matrix}Q = E [ {w}_{d} {w}_{d}^{T} ] \\ = E [ ( {\int }_{0}^{{T}_{s}} [ \begin{matrix}I ( {T}_{s} - u ) \\ I\end{matrix} ] w ( {t}_{k} + u ) du ) ( {\int }_{0}^{{T}_{s}} [ \begin{matrix}I ( {T}_{s} - u ) \\ I\end{matrix} ] w ( {t}_{k} + v ) dv ) ] \\ {\int }_{0}^{{T}_{s}} {\int }_{0}^{{T}_{s}} [ \begin{matrix}I ( {T}_{s} - v ) \\ I\end{matrix} ] [ I ( {T}_{s} - v ) I ] E [ \tilde{w} ( {t}_{k} + u ) \tilde{w} ( {t}_{k} + v ) ] dudv \\ = {\int }_{0}^{{T}_{s}} [ \begin{matrix}{I ( {T}_{s} - u )}^{2} & I ( {T}_{s} - u ) \\ I ( {T}_{s} - u ) & I\end{matrix} ] q ( {t}_{k} + v ) du \\ = q [ \begin{matrix}I \frac{1}{3} {T}_{s}^{3} & I \frac{1}{2} {T}_{s}^{2} \\ I \frac{1}{2} {T}_{s}^{2} & {IT}_{s}\end{matrix} ]\end{matrix} \qquad Formula 12$$

$${Q}_{total} = [ \begin{matrix}Q & 0 \\ 0 & {Q}_{track}\end{matrix} ]$$

where q is the spectral density of the white noise and q is the tuning parameter that corresponds to the estimated process noise.

As disclosed above, due to track installation tolerances, gaps (e.g., the plurality of gaps 229N) may exist in the longitudinal direction between track elements. During operation, the laser sensor (e.g., the laser sensor 233A) may measure the longitudinal track gap, which will result in a very large measurement. Though this measurement is true on the local level, the result is an incorrect approximation of a gap between the track and the respective control plane of the hyperloop vehicle 110. As a result, this measurement does not reflect the relative distance of the hyperloop vehicle 110 to the track elements. To account for this inaccuracy, the Kalman filter recognizes the measurement as an outlier and executes appropriate adjustments to reject the inaccurate measurement.

In order to perform said adjustments, the Kalman filter dynamically evaluates the differences between the predicted and the measured values, then scales the measurement covariance matrix, R, appropriately when an undesirable difference is detected. The real innovation covariance matrix, Γ, is approximated as shown in Formula 13 below.

$$Covariance Matrix Γ Determination ,$$

$${n}_{x} = {y}_{k} = H {\hat{x}}_{k \vert k - 1} \qquad Formula 13$$

$$Γ = \frac{1}{μ} {\sum }_{j = k - μ + 1}^{k} {n}_{j} {n}_{j}^{T}$$

where μ is the number of values in the moving window of time.

One of skill in the art will appreciate that μ is a tuning parameter that will affect the performance of the Kalman filter. When a measurement malfunction exists in the estimation system, the real error will exceed the theoretical one as shown in Formula 14 below.

tr{Γ}≥tr{HP_{k|k-1}H^{T}+R} Formula 14: Real and Theorical Error Relationship,
where tr is the trace of the matrix.

In order to correct for the measurement error, a scaling matrix Sₖ, is added to ensure the following equality holds as shown in Formula 15 below.

τ=HP_{k|k-1}H^{T}+SₖR

Sₖ=(τ−HP_{k|k-1}H^{T})R⁻¹ Formula 15: Scaling Matrix Determination

Under nominal conditions, Sₖ will be less than 1, indicating that the variations in the innovation lie within the theoretical bounds. In this case, Sₖ is an identity matrix. However, if an outlier is detected, the measurement noise covariance may be scaled to ensure that the adjusted theoretical innovation covariance captures this noise. This adaption in Sₖ is performed as shown in Formula 16 below.

Sₖ=diag(s₁, . . . ,s_{N})

sᵢ=max{1S_{i,i}}

Kₖ=P_{k|k-1}H^{T}(HP_{k|k-1}H^{T}+SₖR)⁻¹ Formula 16: Scaling Matrix Adaptation

As such, a decrease in the Kalman gain is achieved for that specific sensor gain, thus removing the effect of the outlier. As a technical effect, the gaps between track elements may be measured and processed as part of state estimation of the hyperloop vehicle 110.

Upon competition of the operations associated with the block 409, the process 401 proceeds to the callout reference A which proceeds to callout reference B at FIG. 4G. The process 401 proceeds to the decision block 411.

The disclosed state estimation may have multiple fault detection functions associated therewith to ensure accuracy, safety, and reliability of: the Kalman filter, sensor-based measurements/data, estimated state, motion control, etc. Examples of fault detection functions include measurement chi square tests, state chi square tests, measurement auto-correlation tests, measurement validity tests, minimum measurement tests, etc.

At the decision block 411, the process 401 determines whether a fault has been detected by the sensor system 321. The process 401 may utilize the plurality of fault tolerance modules 319 in order to capture and/or report a fault to the proper system (e.g., the motion execution module 315). For instance, a current command sent to the engines of the hyperloop vehicle 110 at time to may not be adequately acted on and, as such, a fault may be detected at the fault tolerance module 319. At time t₁, the fault tolerance module 319 will report the failure of the engines to the state estimation module 317 such that the next state estimation may consider the fault (or failure) as part of the generation of a state estimation for a later time, e.g., at the time t₁ using the process 401 (iteratively, in one aspect). If a fault has been detected, the process 401 proceeds along the YES branch to the block 413.

At the block 413, the process 401 addresses the detected fault. In one aspect, as discussed, the state estimation module 317 may adjust a future state estimation (e.g., a state estimation generated by subsequent use of the process 401. In another respect, the motion execution module 315 may adjust the linearized current commands sent to the engines in order to address a potential fault that had been detected by the fault tolerance module 319.

A potential fault may relate to a measurement fault, a state fault, a whiteness of Kalman filter checking, or a combination thereof. Returning to the decision block 411, if a determination is made by the process 401 that a fault has not been detected, the process 401 proceeds along the NO branch to the end block and terminates.

Reference C is shown on FIG. 4A to indicate that the process 401 may be utilized iteratively. For instance, a state estimation generated at time t₀ will reflect the position and/or orientation of the hyperloop vehicle 110 at time t₁. Likewise, at time t₁, the process 401 may determine the position and/or orientation (i.e., the state estimation) at the time t₂. Thus, the process 401 may terminate at the end block and be subsequently executed using previous state estimations to inform the state estimation generation at the block 409 (or generally throughout the process 401).

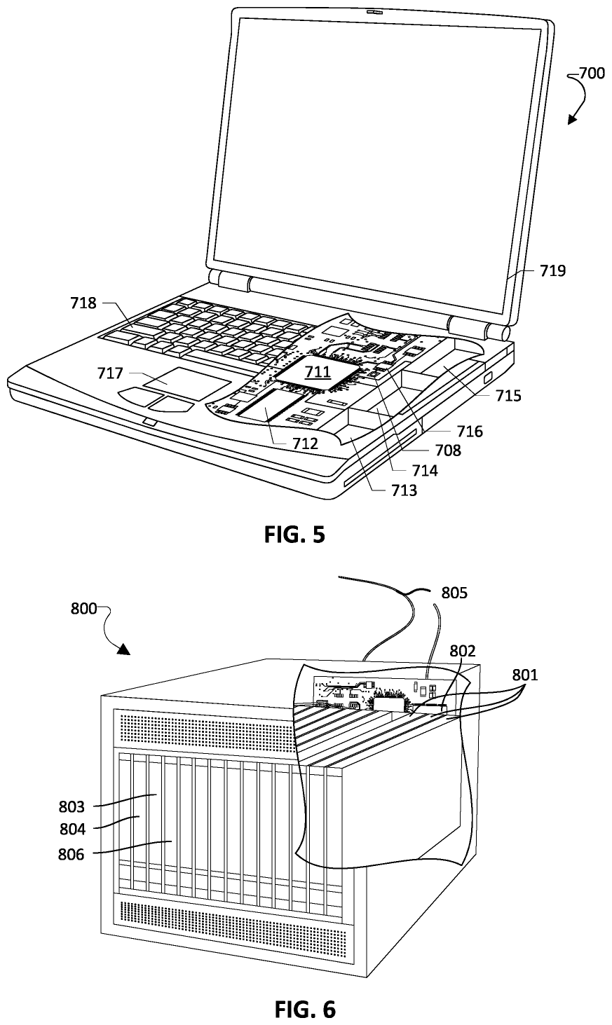

FIG. 5 is a block diagram illustrating a computing device 700 suitable for use with the various aspects described herein. In one aspect, the computing device 700 may be configured to store and execute the state estimation system 301 and the process 401, both of which are disclosed herein, such that a state estimation of the hyperloop vehicle 110 may be determined.

The computing device 700 may include a processor 711 (e.g., an ARM processor) coupled to volatile memory 712 (e.g., DRAM) and a large capacity nonvolatile memory 713 (e.g., a flash device). Additionally, the computing device 700 may have one or more antenna 708 for sending and receiving electromagnetic radiation that may be connected to a wireless data link and/or cellular telephone transceiver 716 coupled to the processor 711. The computing device 700 may also include an optical drive 714 and/or a removable disk drive 715 (e.g., removable flash memory) coupled to the processor 711.

The computing device 700 may include a touchpad touch surface 717 that serves as the computing device's 700 pointing device, and thus may receive drag, scroll, flick etc. gestures similar to those implemented on computing devices equipped with a touch screen display as described above. In one aspect, the touch surface 717 may be integrated into one of the computing device's 700 components (e.g., the display). In one aspect, the computing device 700 may include a keyboard 718 which is operable to accept user input via one or more keys within the keyboard 718. In one configuration, the computing device's 700 housing includes the touchpad 717, the keyboard 718, and the display 719 all coupled to the processor 711. Other configurations of the computing device 700 may include a computer mouse coupled to the processor (e.g., via a USB input) as are well known, which may also be used in conjunction with the various aspects described herein.

FIG. 6 is a block diagram illustrating a server 800 suitable for use with the various aspects described herein. In one aspect, the server 800 may be configured to store and execute the state estimation system 301 and the process 401, both of which are disclosed herein, such that a state estimation of the hyperloop vehicle 110 may be determined.

The server 800 may include one or more processor assemblies 801 (e.g., an x86 processor) coupled to volatile memory 802 (e.g., DRAM) and a large capacity nonvolatile memory 804 (e.g., a magnetic disk drive, a flash disk drive, etc.). As illustrated in instant figure, processor assemblies 801 may be added to the server 800 by insertion into the racks of the assembly. The server 800 may also include an optical drive 806 coupled to the processor 801. The server 800 may also include a network access interface 803 (e.g., an ethernet card, WIFI card, etc.) coupled to the processor assemblies 801 for establishing network interface connections with a network 805. The network 805 may be a local area network, the Internet, the public switched telephone network, and/or a cellular data network (e.g., LTE, 5G, etc.).

The foregoing method descriptions and diagrams/figures are provided merely as illustrative examples and are not intended to require or imply that the operations of various aspects must be performed in the order presented. As will be appreciated by one of skill in the art, the order of operations in the aspects described herein may be performed in any order. Words such as “thereafter,” “then,” “next,” etc. are not intended to limit the order of the operations; such words are used to guide the reader through the description of the methods and systems described herein. Further, any reference to claim elements in the singular, for example, using the articles “a,” “an,” or “the” is not to be construed as limiting the element to the singular.

Various illustrative logical blocks, modules, components, circuits, and algorithm operations described in connection with the aspects described herein may be implemented as electronic hardware, computer software, or combinations of both. To clearly illustrate this interchangeability of hardware and software, various illustrative components, blocks, modules, circuits, operations, etc. have been described herein generally in terms of their functionality. Whether such functionality is implemented as hardware or software depends upon the particular application and design constraints imposed on the overall system. One of skill in the art may implement the described functionality in varying ways for each particular application, but such implementation decisions should not be interpreted as causing a departure from the scope of the claims.

The hardware used to implement various illustrative logics, logical blocks, modules, components, circuits, etc. described in connection with the aspects described herein may be implemented or performed with a general purpose processor, a digital signal processor (“DSP”), an application specific integrated circuit (“ASIC”), a field programmable gate array (“FPGA”) or other programmable logic device, discrete gate logic, transistor logic, discrete hardware components, or any combination thereof designed to perform the functions described herein. A general-purpose processor may be a microprocessor, a controller, a microcontroller, a state machine, etc. A processor may also be implemented as a combination of receiver smart objects, e.g., a combination of a DSP and a microprocessor, a plurality of microprocessors, one or more microprocessors in conjunction with a DSP core, or any other such like configuration. Alternatively, some operations or methods may be performed by circuitry that is specific to a given function.

In one or more aspects, the functions described may be implemented in hardware, software, firmware, or any combination thereof. If implemented in software, the functions may be stored as one or more instructions (or code) on a non-transitory computer-readable storage medium or a non-transitory processor-readable storage medium. The operations of a method or algorithm disclosed herein may be embodied in a processor-executable software module or as processor-executable instructions, both of which may reside on a non-transitory computer-readable or processor-readable storage medium. Non-transitory computer-readable or processor-readable storage media may be any storage media that may be accessed by a computer or a processor (e.g., RAM, flash, etc.). By way of example but not limitation, such non-transitory computer-readable or processor-readable storage media may include RAM, ROM, EEPROM, NAND FLASH, NOR FLASH, M-RAM, P-RAM, R-RAM, CD-ROM, DVD, magnetic disk storage, magnetic storage smart objects, or any other medium that may be used to store program code in the form of instructions or data structures and that may be accessed by a computer. Disk as used herein may refer to magnetic or non-magnetic storage operable to store instructions or code. Disc refers to any optical disc operable to store instructions or code. Combinations of any of the above are also included within the scope of non-transitory computer-readable and processor-readable media. Additionally, the operations of a method or algorithm may reside as one or any combination or set of codes and/or instructions on a non-transitory processor-readable storage medium and/or computer-readable storage medium, which may be incorporated into a computer program product.

The preceding description of the disclosed aspects is provided to enable any person skilled in the art to make, implement, or use the claims. Various modifications to these aspects will be readily apparent to those skilled in the art, and the generic principles defined herein may be applied to other aspects without departing from the scope of the claims. Thus, the present disclosure is not intended to be limited to the aspects illustrated herein but is to be accorded the widest scope consistent with the claims disclosed herein.

1. A method for generation of a state estimation for a hyperloop vehicle, the method comprising:
receiving, at a processor, first sensor data from a sensor system, the sensor system comprising a laser-gap sensor and an inertial-measurement unit, the first sensor data comprising a first laser-based measurement and a first inertial-measurement-based measurement;
generating, at the processor, a first position and a first orientation, the first position and the first orientation being generated from the first sensor data;
generating, at the processor, a predicted position using a Kalman filter, the predicted position being measured with respect to the hyperloop vehicle and a rail;
generating, at the processor, a predicted orientation using the Kalman filter, the predicted orientation being measured with respect to the hyperloop vehicle and the rail; and
sending, at the processor, the predicted position and the predicted orientation to a motion execution controller, the motion execution controller being configured to command at least one engine of the hyperloop vehicle, the commanding causing the hyperloop vehicle to move to the predicted position with the predicted orientation.

2. The method of claim 1, the method further comprising:
determining, at the processor, a noise value, the noise value being associated with a sensor-related deviation, the sensor-related deviation being accounted for by the Kalman filter prior to generating the predicted position, the predicted orientation, or a combination thereof.

3. The method of claim 2, the method further comprising:
calibrating, at the processor, the sensor system to generate a sensor calibration value, the sensor-related deviation being based on the sensor calibration value.

4. The method of claim 1, the method further comprising:
measuring, at the processor, a track bias, the track bias being measured by the laser gap sensor, the track bias being accounted for by the Kalman filter prior to generating the predicted position, the predicted orientation, or a combination thereof.

5. The method of claim 4, wherein the track bias is due to track tolerance, track material variation, track roughness, or a combination thereof.

6. The method of claim 1, the method further comprising:
detecting, at the processor, a longitudinal gap, the longitudinal gap being measured by the laser gap sensor, the longitudinal gap being accounted for by the Kalman filter prior to generating the predicted position, the predicted orientation, or a combination thereof.

7. The method of claim 1, the method further comprising:
detecting, at the processor, a potential fault, the potential fault being accounted for by the Kalman filter prior to generating the predicted position, the predicted orientation, or a combination thereof.

8. The method of claim 7, wherein the potential fault relates to measurement faults, state faults, whiteness of Kalman filter checking, or a combination thereof.

9. The method of claim 7, wherein the detecting is based on measurement chi square tests, state chi square tests, measurement auto-correlation tests, measurement validity tests, minimum measurement tests, or a combination thereof.

10. A state estimation system for generating a state estimation for a hyperloop vehicle, the state estimation system comprising:
a memory;
a sensor system, the sensor system comprising a laser gap sensor and an inertial-measurement unit;
a processor, the processor configured to:
receive first sensor data from the sensor system;
generate a first position and a first orientation, the first position and the first orientation being generated from the first sensor data;
generate a predicted position using a Kalman filter, the predicted position being measured with respect to the hyperloop vehicle and a rail;
generate a predicted orientation using the Kalman filter, the predicted orientation being measured with respect to the hyperloop vehicle and the rail; and
send the predicted position and the predicted orientation to a motion execution controller, the motion execution controller being configured to command at least one engine of the hyperloop vehicle, the commanding causing the hyperloop vehicle to move to the predicted position with the predicted orientation.

11. The state estimation system of claim 10, the processor being further configured to:
determine a noise value, the noise value being associated with a sensor-related deviation, the sensor-related deviation being accounted for by the Kalman filter prior to generating the predicted position, the predicted orientation, or a combination thereof.

12. The state estimation system of claim 11, the processor being further configured to:
calibrate the sensor system to generate a sensor calibration value, the sensor-related deviation being based on the sensor calibration value.

13. The state estimation system of claim 10, the processor being further configured to:
measure a track bias, the track bias being measured by the laser gap sensor, the track bias being accounted for by the Kalman filter prior to generating the predicted position, the predicted orientation, or a combination thereof.

14. The state estimation system of claim 13, wherein the track bias is due to track tolerance, track material variation, track roughness, or a combination thereof.

15. The state estimation system of claim 10, the processor being further configured to:
detect a longitudinal gap, the longitudinal gap being measured by the laser gap sensor, the longitudinal gap being accounted for by the Kalman filter prior to generating the predicted position, the predicted orientation, or a combination thereof.

16. The state estimation system of claim 10, processor being further configured to:
detect a potential fault, the potential fault being accounted for by the Kalman filter prior to generating the predicted position, the predicted orientation, or a combination thereof.

17. The state estimation system of claim 16, wherein the potential fault relates to measurement faults, state faults, whiteness of Kalman filter checking, or a combination thereof.

18. The state estimation system of claim 16, wherein the detecting is based on measurement chi square tests, state chi square tests, measurement auto-correlation tests, measurement validity tests, minimum measurement tests, or a combination thereof.

19. A computer-readable medium storing instructions that, when executed by a computer, cause the computer to:
generate, at a processor, first sensor data from a sensor system, the sensor system comprising a laser-gap sensor and an inertial-measurement unit, the first sensor data comprising a first laser-based measurement and a first inertial-measurement-based measurement;
generate, at the processor, a first position and a first orientation, the first position and the first orientation being generated from the first sensor data;
generate, at the processor, a predicted position using a Kalman filter, the predicted position being measured with respect to the hyperloop vehicle and a rail;
generate, at the processor, a predicted orientation using the Kalman filter, the predicted orientation being measured with respect to the hyperloop vehicle and the rail; and
send, at the processor, the predicted position and the predicted orientation to a motion execution controller, the motion execution controller being configured to command at least one engine of the hyperloop vehicle, the commanding causing the hyperloop vehicle to move to the predicted position with the predicted orientation.

20. The computer-readable medium of claim 19, the instructions further causing the computer to:
measure, at the processor, a track bias, the track bias being measured by the laser gap sensor, the track bias being accounted for by the Kalman filter prior to generating the predicted position, the predicted orientation, or a combination thereof.
